(19) United States
(12) Patent Application Publication
(10) Pub. No.: US 2006/0261441 A1
(43) Pub. Date: Nov. 23, 2006

(54) Process for forming a low carbon, low resistance metal film during the manufacture of a semiconductor device and systems including same

(75) Inventors: Eugene P. Marsh, Boise, ID (US); Brenda D. Kraus, Boise, ID (US)

Correspondence Address: MICRON TECHNOLOGY, INC., 8000 FEDERAL WAY, MAIL STOP 525, BOISE, ID, 83707-0006, US

(73) Assignee: Micron Technology, Inc.

(21) Appl. No.: 11/134,906

(22) Filed: May 23, 2005

(51) Int. Cl. H01L 29/40; H01L 21/44

(52) U.S. Cl. 257/532; 438/396; 438/660; 438/687; 257/734; 257/768

(57) ABSTRACT

A method for forming a conductive feature comprises forming a metal film such as ruthenium then annealing the film in an atmosphere comprising a hydrogen-rich gas such as ammonia, hydrogen, borane, or diborane, or in another gas such as carbon monoxide. The anneal may decrease the carbon content of the film and results in a metal layer having a lower resistance than the preannealed metal film.

### FIELD OF THE INVENTION

This invention relates to the field of semiconductor manufacture and, more particularly, to a method for annealing a metal film which decreases the film's resistance and also may decrease the carbon content of the metal.

### BACKGROUND OF THE INVENTION

Many different types of materials are used in the manufacture of semiconductor memory devices, logic devices, microprocessors, etc. Pure metals are becoming more commonly used in semiconductor manufacture for a wider range of purposes due to the prohibitively high resistance found with nonmetals and metal-containing compounds such as polysilicon, metal silicides, and metal nitrides, particularly with decreasing feature sizes. For example, attempts have been made to manufacture capacitor plates, typically formed from polysilicon, from ruthenium metal. Ruthenium may also be used as a barrier layer to copper migration and as a seed layer for copper plating.

While the formation of a conformal metal layer with good step coverage may be more difficult than the formation of other nonmetals previously used, their use is necessary to produce a reliable semiconductor device. One method for forming a capacitor plate from ruthenium metal is described by U.S. Pat. No. 6,617,248 by Yang, assigned to Micron Technology, Inc., and incorporated herein as if set forth in its entirety. Yang discusses the formation of a container capacitor bottom plate by first forming a layer of ruthenium oxide (RuO₂), then reducing the RuO₂ to Ru metal by exposing the RuO₂ to a hydrogen-rich gas, for example either ammonia (NH₃) or hydrogen gas (H₂).

As discussed in Yang, RuO₂ is not stable at high temperatures and forms an oxidizer. Reducing RuO₂ into Ru metal and O₂ using NH₃ or N₂ also results in the formation of ruthenium tetraoxide (RuO₄) which strongly oxidizes exposed layers such as titanium nitride or layers comprising silicon and forms a dielectric film over the conductive layer. This dielectric film may lead to unwanted opens and a poorly functional or nonfunctional semiconductor device. Yang forms a barrier to prevent oxidation of the polysilicon pads. Many barriers, however, may not sufficiently protect silicon pads from RuO₄, particularly at high temperatures.

Reducing a metal oxide to metal also results in a substantial volumetric decrease of the resulting metal compared with the metal oxide due to the removal of oxygen atoms from the material. Reducing a metal oxide to metal may stress structures formed under the metal oxide, and may damage the structures. Stress may have other undesirable consequences such as causing layers to form at uneven rates and also a change in conductive properties. It is therefore often desirable to avoid stresses resulting from reducing a metal oxide to metal.

In addition to forming metal layers themselves, improving the conductivity and purity of metal layers is a goal of semiconductor process engineers. Increased material conductivity allows the size of a feature, such as the width or cross-sectional area of a metal line, to be decreased while maintaining a resistance within acceptable limits. Forming a metal layer having a higher purity, in addition to improving conductivity, reduces the layer as a source of contamination and improves reliability and longevity of a device.

A method for forming a metal layer with increased conductivity and fewer contaminants would be desirable.

### SUMMARY OF THE INVENTION

The present invention provides a method for annealing a metal layer which results in the formation of a highly conductive metal layer having reduced contamination and reduced oxidation of exposed layers. In accordance with one embodiment of the invention a pure metal layer, particularly a metal which does not form a metal nitride, is formed in accordance with previous methods such as chemical vapor deposition (CVD) or atomic layer deposition (ALD). Metals which do not form metal nitrides include ruthenium, cobalt, platinum, and nickel. The pure metal layer is then annealed in the presence of ammonia (NH₃), borane (BH₃), diborane (B₂H₆), hydrogen gas (H₂), or carbon monoxide (CO). Annealing the completed metal layer as described densifies the metal, possibly by removing contaminants such as carbon, and improves the conductivity of the completed metal layer. Further, undesirable oxidizing byproducts such as a metal tetraoxide are not produced as these gasses are reducing and not oxidizing.

Advantages will become apparent to those skilled in the art from the following detailed description read in conjunction with the appended claims and the drawings attached hereto.

### BRIEF DESCRIPTION OF THE DRAWINGS

FIGS. 1-8 are cross sections depicting in-process structures formed during implementation of an embodiment of the method of the present invention;

FIG. 9 is a cross section depicting a structure formed during implementation of another embodiment of the method of the present invention;

FIG. 10 is an isometric depiction of various components of an electronic system which may be manufactured using devices formed with an embodiment of the present invention; and

FIG. 11 is a block diagram of an exemplary use of the invention to form part of a memory device having a storage transistor array such as may be used in an electronic system as depicted.

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE ILLUSTRATED EMBODIMENTS

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but could be based on silicon-germanium, silicon-on-insulator, silicon-on-sapphire, germanium, or gallium arsenide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein.

The present invention comprises the formation of a metal layer, particularly a metal which does not form a metal nitride, and its subsequent anneal in an atmosphere having a high concentration of hydrogen. Particularly preferred metals include ruthenium, cobalt, platinum, and nickel. While the description below describes the formation of a ruthenium metal layer deposited using chemical vapor deposition (CVD), it is to be understood that any preferred metal may benefit from the present invention regardless of its method of formation (for example through the use of atomic layer deposition) using the inventive process with similar results.

The present invention comprises forming a semiconductor wafer substrate assembly, then forming a metal layer over the assembly. As used herein, a “metal layer” refers to a layer which is a pure metal layer rather than a metal-containing compound such as a metal oxide, metal nitride, metal silicide, etc. A metal layer which is “substantially free from oxygen” includes a metal layer which may have a low percentage of oxygen atoms, for example resulting from reaction with environmental oxygen, but excludes metal oxides. Further, a “metal layer” as used herein may include a native oxide which forms on the metal by exposure to environmental oxygen, unless it is specified that the “metal layer” is free or substantially free from the native oxide. During the anneal of the metal layer this native oxide will not provide sufficient oxygen to form large amounts of an oxidizer such as metal tetraoxide, for example ruthenium tetraoxide (RuO₄), although trace amounts may be present. Thus during this anneal exposed silicon or polysilicon surfaces will not oxidize to such an extend as to interfere with processing, for example resulting in electrical opens, as a result of oxygen which released due to disproportionation of a metal and an oxide. [//this is included to define around Yang if necessary]

One method used to form a ruthenium metal layer begins by placing the wafer assembly into a deposition chamber, or it may remain in a chamber from previous processing. In the chamber, a ruthenium precursor such as tricarbonyl-1,3-cyclohexadiene ruthenium (referred to herein as “CHDR”) is introduced into the chamber at a flow rate of between about 10 sccm to about 2,000 sccm, more preferably at a flow rate of between about 100 sccm and about 1,000 sccm, and most preferably at a flow rate of about 500 sccm. Helium may be used as a carrier gas for the CHDR. The chamber further comprises an environment having a pressure preferably between about 0.1 Torr to about 90 Torr, and more preferably at a pressure of between about 1.0 Torr and about 10.0 Torr. A wafer temperature of between about 100° C. and about 600° C., more preferably between about 150° C. and about 450° C., and most preferably about 210° C. would be sufficient. At the preferred parameters, the ruthenium metal will form at a rate of between about 30 Å/minute and about 120 Å/minute.

After forming the metal layer, it is annealed, preferably in situ. After forming the metal layer the deposition chamber is purged, for example through the introduction of nitrogen (N₂) into the chamber. Next, the chamber is heated to an anneal temperature of between about 500° C. and about 900° C., more preferably to between about 625° C. and about 775° C., and most preferably to about 700° C. At temperature, a hydrogen-rich gas is introduced into the chamber. For purposes of this disclosure, the term “hydrogen-rich gas” refers to non-carbon containing hydrides and reducing gasses with the exception of silanes. These gasses comprise hydrogen (H₂), ammonia (NH₃), diborane (B₂H₆), and borane (BH₃). For example, if B₂H₆, NH₃, and/or BH₃ is used, the gas is introduced into the chamber at a flow rate of between about 100 sccm and about 10,000 sccm, and more preferably at a flow rate of between about 1,000 sccm and about 3,000 sccm. If H₂ is used, it will be introduced into the chamber at a flow rate of between about 100 sccm and about 5,000 sccm. With any of these gasses, pressure within the chamber during the anneal is maintained to between about 100 millitorr and about 900 torr, and more preferably to between about 1,000 millitorr and about 700 torr. The anneal is preferably performed for between about 10 seconds and about 6,000 seconds, and more preferably for about 90 seconds. After annealing the metal layer, wafer processing continues according to techniques known in the art to produce a completed semiconductor device.

Another gas which may be used to anneal a metal to result in decreased resistance but does not fit into the present definition of “hydrogen-rich gas” includes carbon monoxide (CO). While testing has not been performed using this gas, it is believed by the inventors herein that CO will function sufficiently for purposes of the present invention. The anneal and gas delivery conditions using CO would be within the range described above for the other gasses.

Annealing the completed metal layer in the presence of BH₃, NH₃, B₂H₆, H₂, or CO decreases the resistance of the completed metal. For example, a ruthenium metal feature which has an as-deposited resistivity of about 110 μΩcm was calculated to have a post NH₃ anneal resistivity of about 12 μΩcm or less. By comparison, the same film annealed only in nitrogen (N₂) had a resistivity of about 55 μΩcm. The decrease in resistivity may be due to a reduction in contaminants such as carbon within the metal.

During the anneal the metal feature will decrease in volume, although the reduction has not been quantified. As discussed above, this reduction in volume may result from the decrease of the carbon contaminants within the metal. Unlike processes which reduce a metal oxide to a metal layer and result in substantial stresses on other layers from a large volumetric decrease of the metal compared to the metal oxide, annealing the pure metal layer to reduce the resistance provides a substantially stress-free metal layer.

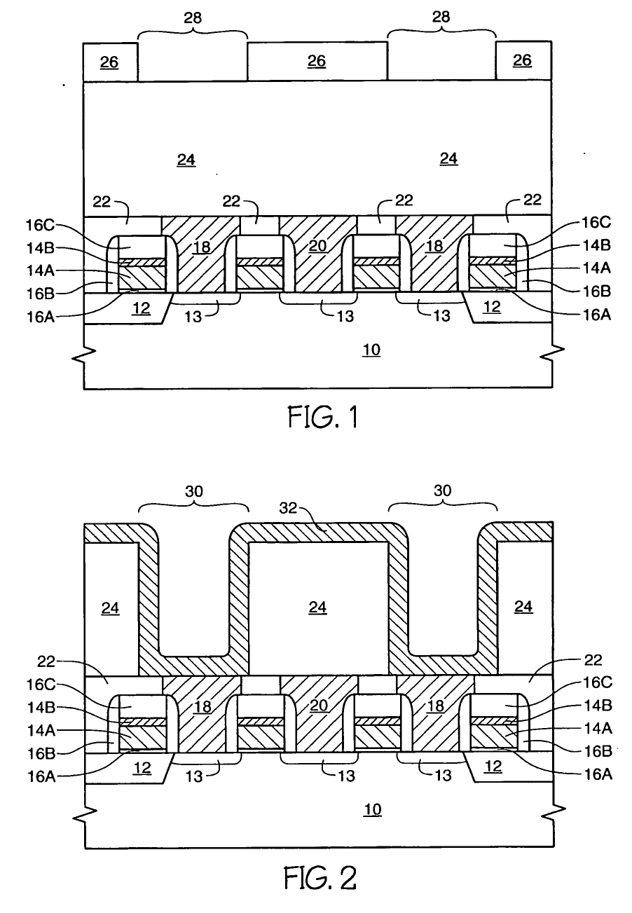

The present invention may be used to form any number of different structures such as a container capacitor bottom plate and/or top plate and a solder wetting layer for wafer level processing. A first embodiment of an inventive method to form both top and bottom capacitor plates (electrodes) for a container capacitor such as a memory cell is depicted in FIGS. 1-8. While both plates are depicted as being formed using the inventive process, either plate alone may be manufactured using the present process with the other plate being formed conventionally.

FIG. 1 depicts a semiconductor wafer substrate assembly comprising a semiconductor wafer 10, field oxide 12, doped wafer areas 13, transistor control gates typically comprising a polysilicon gate 14A and silicide 14B, and surrounding dielectric typically comprising gate oxide 16A, nitride spacers 16B, and capping layer 16C, for example tetraethyl orthosilicate (TEOS). The device further comprises polysilicon contact pads including pads 18 to which the ruthenium metal container capacitor bottom plate will be electrically coupled and pads 20 (only one depicted) which will form a portion of a digit line contact to the wafer 10. FIGS. 1-8 further depict a dielectric layer 22, for example borophosphosilicate glass (BPSG), which separates pads 18, 20.

Also depicted is a second layer of dielectric 24 which may be one or more layers of TEOS and/or BPSG. With current technology, layer 24 may be about 14,000 Å thick. A layer of photoresist 26 defines openings 28 which overlie pads 18 to which the container capacitors will be electrically coupled. The structure of FIG. 1 is exposed to a vertical anisotropic etch which removes dielectric layer 24 selective to the polysilicon contact pads 18.

FIG. 2 depicts openings 30 in dielectric 24 which result from the etch of the FIG. 1 structure. The etch exposes pads 18, while the pads 18 contact the doped regions 13. Pads 18 decrease the amount of oxide which the etch of the FIG. 1 structure must remove. Without pads 18, the etch would be required to remove the additional thickness of oxide layer 22 to expose doped regions 13.

After forming the openings 30, a blanket layer of metal 32 such as ruthenium metal is formed over exposed surfaces including pads 18. A ruthenium metal layer between about 40 Å thick and about 300 Å thick would be sufficient for this exemplary embodiment. Such as layer may be formed using one of the methods described above. However, the method of reducing RuO₂ to Ru metal is not preferred in this particular exemplary embodiment of the invention, as the conversion of RuO₂ to Ru metal will result in the oxidation of pads 18 and an undesirable electrical open between pads 18 and Ru layer 32.

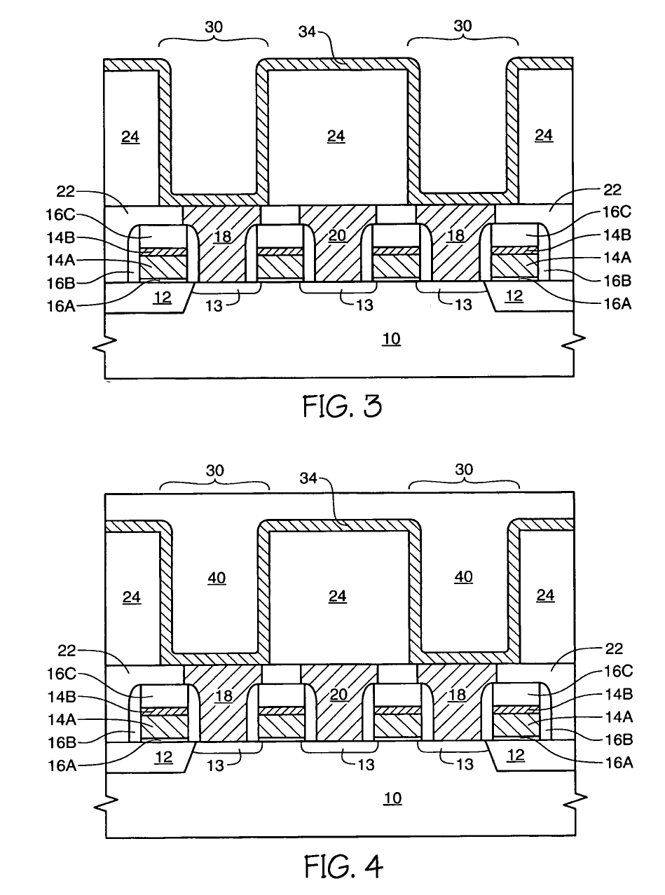

Next, the metal layer 32 is annealed according to an embodiment of the present invention to result in the annealed layer 34 as depicted in FIG. 3. While the anneal may densify layer 32 to result in layer 34, the reduction depicted between FIGS. 2 and 3 is for illustration purposes only, as the actual reduction will be less than that depicted, although the reduction has not been quantified. For the anneal process, the structure of FIG. 2 may remain in a deposition chamber used to form the metal layer 32. The anneal may be performed by first heating the deposition chamber to an anneal temperature, for example between about 500° C. and about 1,000° C., preferably about 700° C. At temperature, a hydrogen-rich gas is introduced into the chamber. For example, at least one of NH₃, BH₃, B₂H₆, H₂, or CO is introduced into the chamber at a flow rate of between about 100 sccm and about 10,000 sccm, or H₂ at a flow rate of between about 100 sccm and about 5,000 sccm. With either of these gasses, pressure within the chamber during the anneal is maintained to between about 100 millitorr and about 900 torr. The anneal is preferably performed for between about 10 seconds and about 6,000 seconds. Due to the densification of the ruthenium metal layer from the anneal, the thickness of the layer 34 decreases but, as previously stated, the densification has not been quantified.

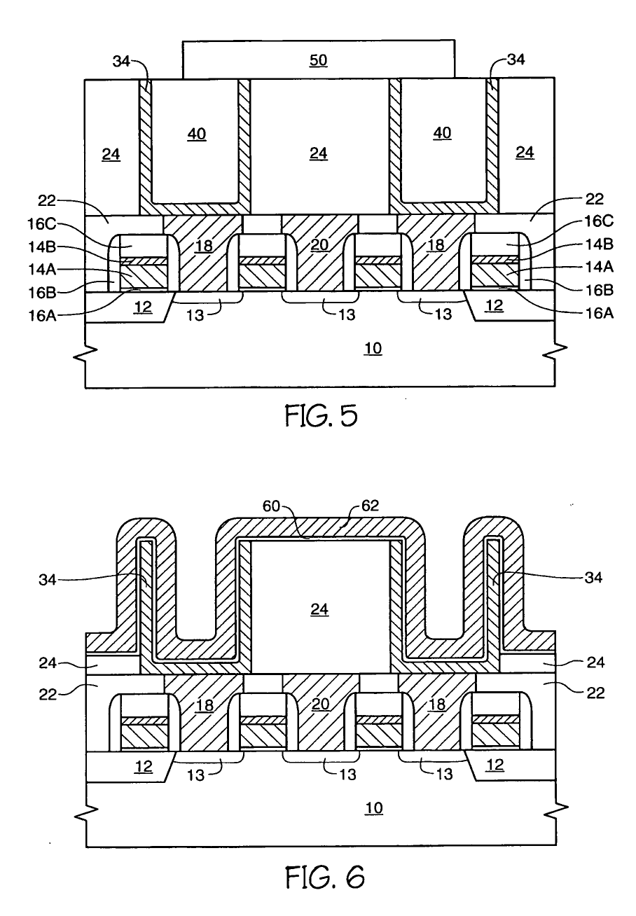

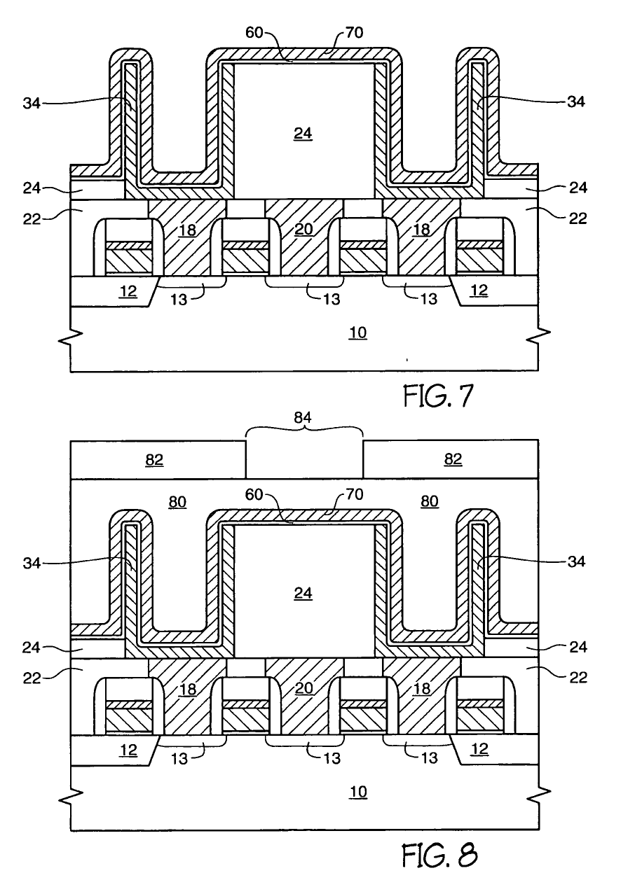

Subsequently, the openings 30 are filled with a sacrificial protective material 40 such as photoresist as depicted in FIG. 4. The metal layer 34 and a portion of dielectric 24 are etched, for example using mechanical planarization such as chemical mechanical planarization (CMP). This removes the ruthenium metal from the horizontal surface of dielectric 24 to result in the ruthenium metal capacitor bottom plate structures 34 of FIG. 5. A photoresist mask 50 is formed over the structure to protect the oxide layer between the two container capacitors depicted, then an oxide etch is completed to remove a portion of the exposed oxide 24 and to result in oxide 24 as depicted in FIG. 6. Next, the photoresist layers 40, 50 of FIG. 5 are removed and a blanket cell dielectric layer 60 is formed.

Subsequently, a metal capacitor top plate is formed, for example from ruthenium metal using one of the processes described above, resulting in the metal layer 62 of FIG. 6. The metal layer 62 is then annealed, for example in the presence of NH₃ or H₂ according to one of the processes described above, to result in the densified ruthenium metal layer 70 as depicted in FIG. 7. Again, the severity of the volumetric decrease during the anneal of layer 62 to result in layer 70 is for illustration purposes only, as the actual decrease will be less than that depicted. As depicted in FIG. 8, a planar layer of BPSG 80, which with current technology has a thickness of about 4,000 Å, is formed over the FIG. 7 structure, then a patterned photoresist layer 82 is formed which defines an opening 84 which will expose digit line contact pad 20. Wafer processing continues according to techniques known in the art to form a semiconductor memory device.

Capacitor plates formed in accordance with the present embodiment will have reduced resistance compared with similar sized plates formed from the same material, thereby increasing the capacitance. Further, contamination is decreased, possibly through a reduction in the carbon content of the layer.

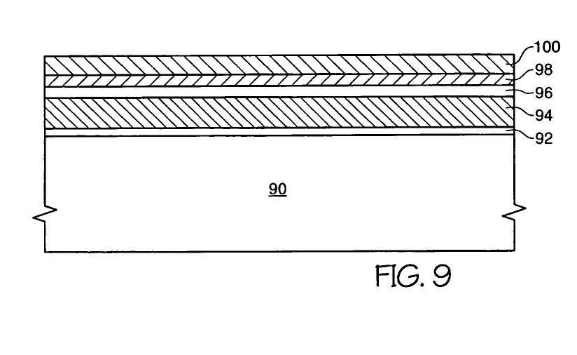

FIG. 9 depicts a use of the inventive densified metal layer as a barrier layer or as a copper seed layer, or as both a barrier layer and a seed layer. FIG. 9 depicts a semiconductor wafer substrate assembly 90 comprising a semiconductor wafer, and likely various other features which are not individually depicted. After forming the semiconductor wafer substrate assembly 90, a dielectric layer 92 may be formed to insulate metal feature 94 from the substrate assembly 90. Next, an interlayer dielectric 96 is formed, and a densified metal layer 98 is formed in accordance with previous embodiments, for example by forming a metal layer then annealing the metal layer in at least one of BH₃, B₂H₆, NH₃, and H₂. After annealing layer 98, a layer 100 such as copper is formed over the densified metal layer 98.

In use as a barrier layer, if layer 100 is formed directly on dielectric layer 96, metal layer 100 will provide a mobile ion source for layer 96. Mobile ions may migrate along dielectric 96 and change the conductivity of a conductive layer such as polysilicon (not depicted) which contacts the dielectric layer 96. The inventive layer 98 used as a barrier layer is more stable than the copper layer 100 and will reduce or eliminate mobile ion contamination of dielectric layer 96. In use as a seed layer, layer 98 facilitates deposition of copper layer (or copper based layer) 100.

While the processes herein describe the use of a thermal anneal, it is contemplated that a plasma anneal may also function sufficiently with the prescribed gasses. The wafer temperature during the plasma anneal may be lower than that described for the thermal anneal, possibly as low as room temperature but up to the maximum described for the thermal anneal. Plasma power may be in the range of 25 watts to 1,200 watts, and possibly higher depending on the maximum power allowable by the individual production tool. Various conditions for a plasma anneal may be determined by one of ordinary skill in the art.

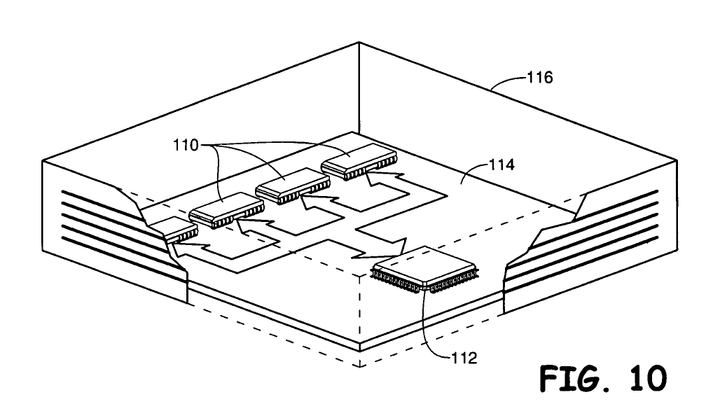

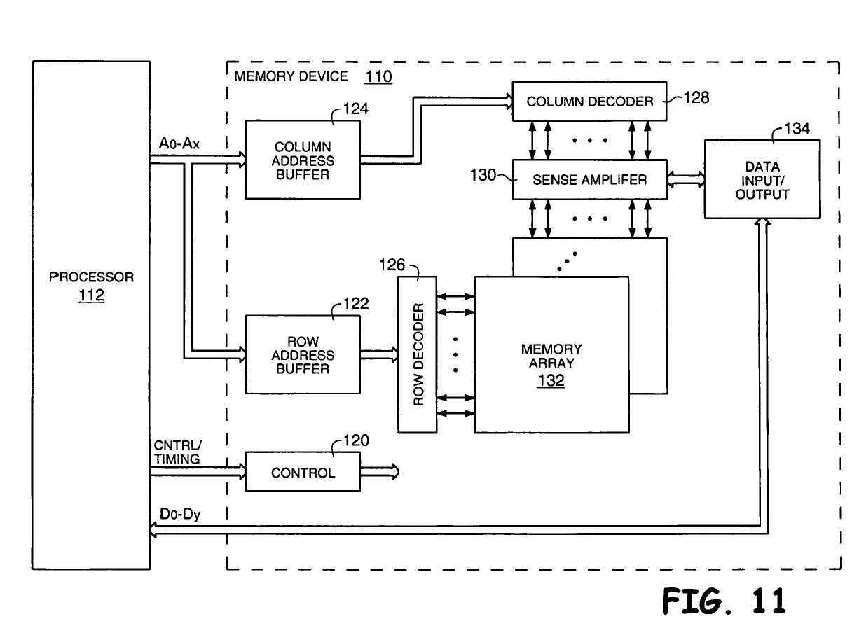

As depicted in FIG. 10, a semiconductor device 110 formed in accordance with the invention may be attached along with other devices such as a microprocessor 112 to a printed circuit board 114, for example to a computer motherboard or as a part of a memory module used in a personal computer, a minicomputer, or a mainframe 116. FIG. 10 may also represent use of device 110 in other electronic devices comprising a housing 116, for example devices comprising a microprocessor 112, related to telecommunications, the automobile industry, semiconductor test and manufacturing equipment, consumer electronics, or virtually any piece of consumer or industrial electronic equipment.

The process and structure described herein can be used to manufacture a number of different structures comprising a metal layer formed according to the inventive process to result in a densified metal layer having decreased resistance and reduced contamination compared with conventional layers. FIG. 11, for example, is a simplified block diagram of a memory device such as a dynamic random access memory having container capacitors and other features which may be formed using an embodiment of the present invention. The general operation of such a device is known to one skilled in the art. FIG. 11 depicts a processor 112 coupled to a memory device 110, and further depicts the following basic sections of a memory integrated circuit: control circuitry 120; row 122 and column 124 address buffers; row 126 and column 128 decoders; sense amplifiers 130; memory array 132; and data input/output 134.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

What is claimed is:

1. A method used during the fabrication of a semiconductor device, comprising:
providing a semiconductor wafer substrate assembly;
forming a metal layer on the semiconductor wafer substrate assembly, wherein the metal layer is substantially free from oxygen atoms and has a first resistivity; and
annealing the metal layer in the presence of a hydrogen-rich gas or carbon monoxide, wherein, subsequent to the annealing, the metal layer has a second resistivity which is less than the first resistivity.

2. The method of claim 1 wherein the anneal of the metal layer occurs in the presence of a hydrogen-rich gas selected from the group consisting of ammonia, borane, diborane, and hydrogen.

3. The method of claim 1 wherein the anneal of the metal layer occurs in the presence of carbon monoxide.

4. The method of claim 1 further comprising:
placing the semiconductor wafer substrate assembly into a deposition chamber;
heating the semiconductor wafer substrate assembly to an anneal temperature of between about 500° C. and about 1,000° C.; and
with the semiconductor wafer substrate assembly at the anneal temperature, introducing the hydrogen-rich gas or the carbon monoxide into the deposition chamber.

5. The method of claim 4 further comprising maintaining a pressure within the deposition chamber to between about 100 millitorr and about 900 torr during the anneal.

6. The method of claim 1 further comprising decreasing a volume of the metal layer during the anneal.

7. The method of claim 1 wherein the first resistivity is about 110 μΩcm and the second resistivity is about 12 μΩcm or less.

8. The method of claim 1 further comprising decreasing a carbon concentration within the metal layer during the anneal.

9. A method used during fabrication of a semiconductor device, comprising:
providing a semiconductor wafer substrate assembly having a polysilicon contact pad;
forming a dielectric layer having a recess therein over the semiconductor wafer substrate assembly, wherein the polysilicon contact pad is exposed at a bottom of the recess
with the polysilicon contact pad exposed at the bottom of the recess, forming a blanket metal layer within the recess which contacts the polysilicon contact pad;
annealing the metal layer in the presence of a hydrogen-rich gas or carbon monoxide;
subsequent to annealing the metal layer, forming a capacitor cell dielectric layer on the metal layer; and
forming a capacitor top plate on the capacitor cell dielectric layer,
wherein the metal layer, the capacitor cell dielectric layer, and the capacitor top plate form at least one capacitor.

10. The method of claim 9 wherein the metal layer is a material selected from the group consisting of ruthenium, cobalt, platinum, and nickel.

11. The method of claim 9 wherein the metal layer is a first metal layer and the formation of the capacitor top plate layer comprises:
forming a second metal layer over the capacitor cell dielectric layer; and
annealing the second metal layer in the presence of a hydrogen-rich gas or carbon monoxide.

12. The method of claim 11 wherein the first metal layer and the second metal layer are metals selected from the group consisting of ruthenium, cobalt, platinum, and nickel.

13. The method of claim 12 wherein:
the anneal of the first metal layer changes a resistivity of the first metal layer from about 110 μΩcm prior to the anneal of the first metal layer to about 12 μΩcm or less after the anneal of the first metal layer; and
the anneal of the second metal layer changes a resistivity of the first metal layer from about 110 μΩcm prior to the anneal of the second metal layer to about 12 μΩcm or less after the anneal of the second metal layer.

14. The method of claim 13 wherein:
the anneal of the first metal layer results in a volumetric decrease of the first metal layer; and
the anneal of the second metal layer results in a volumetric decrease of the second metal layer.

15. The method of claim 9 wherein the metal is annealed in the presence of a hydrogen-rich gas selected from the group consisting of ammonia, borane, diborane, and hydrogen gas.

16. The method of claim 9 wherein the metal is annealed in the presence of carbon monoxide.

17. The method of claim 9 wherein the anneal of the metal layer comprises:
placing the metal layer into a chamber;
heating the semiconductor wafer substrate assembly to an anneal temperature of between about 500° C. and about 1,000° C.; and
at the anneal temperature, introducing at least one of ammonia, borane, hydrogen gas, diborane, and carbon monoxide into the chamber.

18. The method of claim 17 further comprising maintaining a pressure within the chamber of between about 100 millitorr and about 900 torr during the introduction of the hydrogen-rich gas or carbon monoxide.

19. A method for fabricating a semiconductor device, comprising:
providing a semiconductor wafer substrate assembly;
forming a metal layer having a first resistivity on the semiconductor wafer substrate assembly;
annealing the metal layer in the presence of a hydrogen-rich gas or carbon monoxide, wherein annealing the metal layer decreases the resistivity of the metal layer to a second resistivity;
subsequent to annealing the metal layer, forming a copper layer on the metal layer.

20. The method of claim 19 wherein the metal layer functions as a barrier layer to prevent mobile ions from the copper layer from contacting the semiconductor wafer substrate assembly.

21. The method of claim 19 wherein the metal layer functions as a seed layer to facilitate formation of the copper layer over the semiconductor wafer substrate assembly.

22. The method of claim 19 wherein the metal layer is a pure metal selected from the group consisting of ruthenium, cobalt, platinum, and nickel.

23. A semiconductor device, comprising:
a semiconductor wafer substrate assembly comprising a dielectric layer; and
an annealed, substantially stress-free metal layer on the dielectric layer.

24. The semiconductor device of claim 23 wherein the metal layer forms a plate of a memory device container capacitor.

25. The semiconductor device of claim 23 wherein the metal layer comprises a pure metal selected from the group consisting of ruthenium, cobalt, platinum, and nickel.

26. An electronic device comprising a semiconductor device, wherein the semiconductor device comprises:
a semiconductor wafer substrate assembly comprising a dielectric layer; and
an annealed, substantially stress-free metal layer on the dielectric layer.

27. The electronic device of claim 26 wherein the metal layer forms a plate of a memory device container capacitor.

28. The electronic device of claim 26 wherein the metal layer comprises a pure metal selected from the group consisting of ruthenium, cobalt, platinum, and nickel.
